(19) United States
(12) Patent Application Publication
(10) Pub. No.: US 2026/0215186 A1
(43) Pub. Date: Jul. 23, 2026

(54) ETCHING METHOD AND PLASMA PROCESSING APPARATUS

(71) Applicant: Tokyo Electron Limited, Tokyo (JP)

(72) Inventors: Takatoshi ORUI, Hillsboro, OR (US); Masanori HOSOYA, Miyagi (JP)

(73) Assignee: Tokyo Electron Limited, Tokyo (JP)

(21) Appl. No.: 19/568,026

(22) Filed: Mar. 16, 2026

Related U.S. Application Data
(63) Continuation of application No. PCT/JP2024/034002, filed on Sep. 24, 2024.

(30) Foreign Application Priority Data
Sep. 28, 2023 (JP) 2023-168607

(51) Int. Cl. H10P 50/28; H01J 37/32; H10P 50/00

(52) U.S. Cl. CPC H10P 50/283; H01J 37/32146; H01J 37/3244; H10P 50/73; H01J 2237/3341

(57) ABSTRACT

An etching method includes (a) providing a substrate, the substrate including a first region and a second region, (b) forming a deposit on the first region with a first plasma generated from a first process gas, (c) irradiating the deposit with an electron beam to modify the deposit, simultaneously with the (b) or after the (b), and (d) etching the second region with a second plasma generated from a second process gas, after the (c), in a state where the irradiation with the electron beam is stopped.

### CROSS-REFERENCE TO RELATED APPLICATIONS

This application is a continuation application of PCT Application No. PCT/JP2024/034002, filed on Sep. 24, 2024, which claims the benefit of priority from Japanese Patent Application No. 2023-168607, filed on Sep. 28, 2023. The entire contents of the above listed PCT and priority applications are incorporated herein by reference.

### BACKGROUND

### Field

Example embodiments of the present disclosure relate to an etching method and a plasma processing apparatus.

### Description of the Related Art

Japanese Unexamined Patent Publication No. 2020-515063 discloses a method of monitoring and controlling a process of modifying a surface of a layer formed on a substrate with plasma. In this method, a surface-modifying gas is allowed to flow into a plasma processing chamber of a plasma processing system. A plasma is generated in the plasma processing chamber to start a surface modification process of the layer formed on the substrate. In the surface modification process, a resist cure modification is performed by an electron beam.

### SUMMARY

In one example embodiment, an etching method includes (a) providing a substrate, the substrate including a first region and a second region, (b) forming a deposit on the first region with a first plasma generated from a first process gas, (c) irradiating the deposit with an electron beam to modify the deposit, simultaneously with the (b) or after the (b), and (d) etching the second region with a second plasma generated from a second process gas, after the (c), in a state where the irradiation with the electron beam is stopped.

### BRIEF DESCRIPTION OF THE DRAWINGS

FIG. 1 is a diagram for describing a configuration example of a plasma processing system.

FIG. 2 is a diagram for describing a configuration example of a capacitively coupled plasma processing apparatus.

FIG. 3 is a flowchart of an etching method according to one example embodiment.

FIG. 4 is a partially enlarged view of an example of a substrate to which the method in FIG. 3 may be applied.

FIG. 5 is a partially enlarged cross-sectional view of an example of a substrate related to each step of the etching method according to one example embodiment.

FIG. 6 is a partially enlarged cross-sectional view of an example of a substrate related to each step of the etching method according to one example embodiment.

FIG. 7 is a partially enlarged cross-sectional view of an example of a substrate related to each step of the etching method according to one example embodiment.

FIG. 8 is a partially enlarged cross-sectional view of an example of a substrate related to each step of the etching method according to one example embodiment.

FIG. 9 is a timing chart related to the etching method according to one example embodiment.

FIG. 10 is a timing chart related to an etching method according to another example embodiment.

FIG. 11 is a timing chart related to an etching method according to another example embodiment.

FIG. 12 is a timing chart related to an etching method according to another example embodiment.

FIG. 13 is a timing chart related to an etching method according to another example embodiment.

FIG. 14 is a diagram for describing a configuration example of a plasma processing apparatus including an electron beam irradiation source.

FIG. 15 is a diagram for describing another configuration example of the plasma processing apparatus including the electron beam irradiation source.

FIG. 16 is a flowchart of an etching method according to another example embodiment.

FIG. 17 is a partially enlarged cross-sectional view of an example of a substrate related to each step of the etching method according to another example embodiment.

FIG. 18 is a partially enlarged cross-sectional view of an example of a substrate related to each step of the etching method according to another example embodiment.

FIG. 19 is a partially enlarged cross-sectional view of an example of a substrate related to each step of the etching method according to another example embodiment.

FIG. 20 is a partially enlarged cross-sectional view of an example of a substrate related to each step of the etching method according to another example embodiment.

### DETAILED DESCRIPTION

Hereinafter, various example embodiments will be described in detail with reference to the drawings. In the drawing, the same or equivalent portions are denoted by the same reference signs.

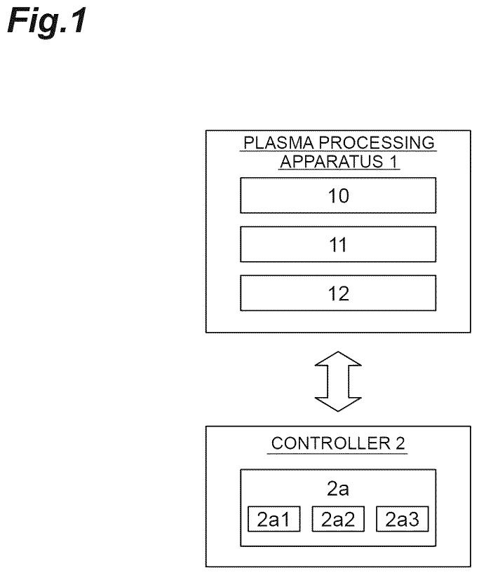

FIG. 1 is a diagram for describing a configuration example of a plasma processing system. In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 further has at least one gas supply port for supplying at least one process gas into the plasma processing space and at least one gas exhaust port for exhausting gases from the plasma processing space. The gas supply port is connected to a gas supply 20 described later and the gas exhaust port is connected to a gas exhaust system 40 described later. The substrate support 11 is disposed in the plasma processing space and has a substrate support surface for supporting the substrate.

The plasma generator 12 is configured to generate a plasma from the at least one process gas supplied into the plasma processing space. The plasma formed in the plasma processing space may be a capacitively coupled plasma (CCP), an inductively coupled plasma (ICP), an electron-cyclotron-resonance (ECR) plasma, a helicon wave plasma (HWP), or a surface wave plasma (SWP), or the like. In addition, various types of plasma generators including an alternating current (AC) plasma generator and a direct current (DC) plasma generator may be used. In one embodiment, AC signal (AC power) used in the AC plasma generator has a frequency in a range of 100 kHz to 10 GHz. Therefore, the AC signal includes a radio frequency (RF) signal and a microwave signal. In one embodiment, the RF signal has a frequency in a range of 100 kHz to 150 MHz.

The controller 2 processes computer executable instructions causing the plasma processing apparatus 1 to execute various steps described in the present disclosure. The controller 2 may be configured to control individual elements of the plasma processing apparatus 1 such that these elements execute the various steps. In one embodiment, the controller 2 may be partially or entirely incorporated into the plasma processing apparatus 1. The controller 2 may include a processor 2a1, a storage 2a2, and a communication interface 2a3. The controller 2 is implemented in, for example, a computer 2a. The processor 2a1 may be configured to read out a program from the storage 2a2, and then perform various control operations by executing the read-out program. This program may be stored in the storage 2a2 in advance, or may be acquired via the medium when necessary. The acquired program is stored in the storage 2a2, and then the processor 2a1 reads out the program from the storage 2a2 to execute the program. The medium may be various storage media that can be read by the computer 2a or may be a communication line connected to the communication interface 2a3. The processor 2a1 may be a central processing unit (CPU). The storage 2a2 may include a random-access memory (RAM), a read-only memory (ROM), a hard disk drive (HDD), a solid-state drive (SSD), or a combination thereof. The communication interface 2a3 may communicate with the plasma processing apparatus 1 via the communication line, such as a local area network (LAN).

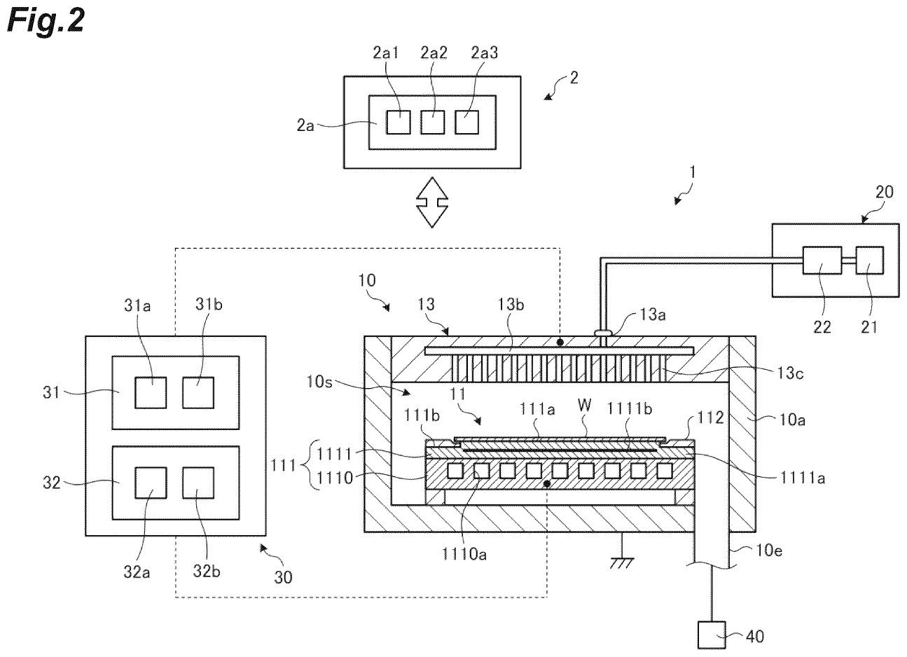

Hereinafter, a configuration example of a capacitively coupled plasma processing apparatus, which is an example of the plasma processing apparatus 1, will be described. FIG. 2 is a diagram for describing the configuration example of the capacitively coupled plasma processing apparatus.

The capacitively coupled plasma processing apparatus 1 includes the plasma processing chamber 10, the gas supply 20, a power supply 30, and a gas exhaust system 40. In addition, the plasma processing apparatus 1 includes a substrate support 11 and a gas introducer. The gas introducer is configured to introduce at least one process gas into the plasma processing chamber 10. The gas introducer includes a shower head 13. The substrate support 11 is disposed in the plasma processing chamber 10. The shower head 13 is disposed above the substrate support 11. In one embodiment, the shower head 13 constitutes at least a part of the ceiling of the plasma processing chamber 10. The plasma processing chamber 10 has a plasma processing space 10s that is defined by the shower head 13, a side wall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a body 111 and a ring assembly 112. The body 111 has a central region 111a for supporting a substrate W and an annular region 111b for supporting the ring assembly 112. A wafer is an example of the substrate W. The annular region 111b of the body 111 surrounds the central region 111a of the body 111 in a plan view. The substrate W is disposed on the central region 111a of the body 111, and the ring assembly 112 is disposed on the annular region 111b of the body 111 to surround the substrate W on the central region 111a of the body 111. Therefore, the central region 111a is also referred to as a substrate support surface for supporting the substrate W, and the annular region 111b is also referred to as a ring support surface for supporting the ring assembly 112.

In one embodiment, the body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a also has the annular region 111b. In addition, other members surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. In addition, at least one RF/DC electrode coupled to an RF power supply 31 and/or a DC power supply 32 to be described later may be disposed in the ceramic member 1111a. In this case, the at least one RF/DC electrode functions as the lower electrode. In a case where a bias RF signal and/or a DC signal to be described later is supplied to at least one RF/DC electrode, the RF/DC electrode is also referred to as a bias electrode. The conductive member of the base 1110 and at least one RF/DC electrode may function as a plurality of lower electrodes. In addition, the electrostatic electrode 1111b may function as the lower electrode. Therefore, the substrate support 11 includes at least one lower electrode.

The ring assembly 112 includes one or a plurality of annular members. In one embodiment, the one or plurality of annular members include one or a plurality of edge rings and at least one cover ring. The edge ring is formed of a conductive material or an insulating material, and the cover ring is formed of an insulating material.

In addition, the substrate support 11 may include a temperature adjusting module that is configured to adjust at least one of the electrostatic chuck 1111, the ring assembly 112, and the substrate to a target temperature. The temperature adjusting module may include a heater, a heat transfer medium, a flow path 1110a, or a combination thereof. A heat transfer fluid, such as brine or gas, flows into the flow path 1110a. In one embodiment, the flow path 1110a is formed in the base 1110, and one or a plurality of heaters are disposed in the ceramic member 1111a of the electrostatic chuck 1111. In addition, the substrate support 11 may further include a heat transfer gas supply configured to supply a heat transfer gas to a gap between a back surface of the substrate W and the central region 111a.

The shower head 13 is configured to introduce at least one process gas from the gas supply 20 into the plasma processing space 10s. The shower head 13 includes at least one gas supply port 13a, at least one gas diffusion chamber 13b, and a plurality of gas introduction ports 13c. The process gas supplied to the gas supply port 13a passes through the gas diffusion chamber 13b and is introduced into the plasma processing space 10s from the plurality of gas introduction ports 13c. In addition, the shower head 13 includes at least one upper electrode. The gas introducer may include one or a plurality of side gas injectors (SGI) attached to one or a plurality of openings formed in the side wall 10a, in addition to the shower head 13.

The gas supply 20 may include at least one gas source 21 and at least one flow controller 22. In one embodiment, the gas supply 20 is configured to supply at least one process gas from the respective corresponding gas source 21 through the respective corresponding flow controller 22 to the shower head 13. Each flow controller 22 may include, for example, a mass flow controller or a pressure-controlled flow controller. Further, the gas supply 20 may include at least one flow rate modulation device that modulates or pulses the flow rate of the at least one process gas.

The power supply 30 includes an RF power supply 31 coupled to the plasma processing chamber 10 via at least one impedance matching circuit. The RF power supply 31 is configured to supply at least one RF signal (RF power) to at least one lower electrode and/or at least one upper electrode. As a result, plasma is formed from at least one process gas supplied to the plasma processing space 10s. Therefore, the RF power supply 31 may function as at least a part of the plasma generator 12. In addition, by supplying the bias RF signal to at least one lower electrode, a bias potential is generated on the substrate W, and ion components in the formed plasma can be drawn into the substrate W.

In one embodiment, the RF power supply 31 includes a first RF generator 31a and a second RF generator 31b. The first RF generator 31a is coupled to the at least one lower electrode and/or the at least one upper electrode via the at least one impedance matching circuit and is configured to generate a source RF signal (source RF power) for generating a plasma. In one embodiment, the source RF signal has a frequency in a range of 10 MHz to 150 MHz. In one embodiment, the first RF generator 31a may be configured to generate a plurality of source RF signals having different frequencies. The generated one or plurality of source RF signals are supplied to at least one lower electrode and/or at least one upper electrode.

The second RF generator 31b is coupled to the at least one lower electrode via the at least one impedance matching circuit and is configured to generate a bias RF signal (bias RF power). The frequency of the bias RF signal may be the same as or different from the frequency of the source RF signal. In one embodiment, the bias RF signal has a frequency lower than the frequency of the source RF signal. In one embodiment, the bias RF signal has a frequency in a range of 100 kHz to 60 MHz. In one embodiment, the second RF generator 31b may be configured to generate a plurality of bias RF signals having different frequencies. The generated one or plurality of bias RF signals are supplied to at least one lower electrode. In addition, in various embodiments, at least one of the source RF signal and the bias RF signal may be pulsed.

In addition, the power supply 30 may include the DC power supply 32 coupled to the plasma processing chamber 10. The DC power supply 32 includes a first DC generator 32a and a second DC generator 32b. In one embodiment, the first DC generator 32a is connected to the at least one lower electrode and is configured to generate a first DC signal. The generated first DC signal is applied to at least one lower electrode. In one embodiment, the second DC generator 32b is connected to the at least one upper electrode and is configured to generate a second DC signal. The generated second DC signal is applied to at least one upper electrode.

In various embodiments, the first and second DC signals may be pulsed. In this case, a sequence of voltage pulses is applied to at least one lower electrode and/or at least one upper electrode. The voltage pulse may have a pulse waveform of a rectangular, trapezoidal, triangular, or a combination thereof. In one embodiment, a waveform generator for generating the sequence of voltage pulses from the DC signal is connected between the first DC generator 32a and at least one lower electrode. Therefore, the first DC generator 32a and the waveform generator constitute a voltage pulse generator. In a case where the second DC generator 32b and the waveform generator constitute the voltage pulse generator, the voltage pulse generator is connected to at least one upper electrode. The voltage pulse may have a positive polarity or may have a negative polarity. In addition, the sequence of the voltage pulses may include one or a plurality of positive-polarity voltage pulses and one or a plurality of negative-polarity voltage pulses in one cycle. The first and second DC generators 32a and 32b may be provided in addition to the RF power supply 31, or the first DC generator 32a may be provided instead of the second RF generator 31b.

The gas exhaust system 40 may be connected to, for example, a gas exhaust port 10e provided in the bottom of the plasma processing chamber 10. The gas exhaust system 40 may include a pressure regulation valve and a vacuum pump. The pressure in the plasma processing space 10s is adjusted by the pressure regulation valve. The vacuum pump may include a turbo molecular pump, a dry pump, or a combination thereof.

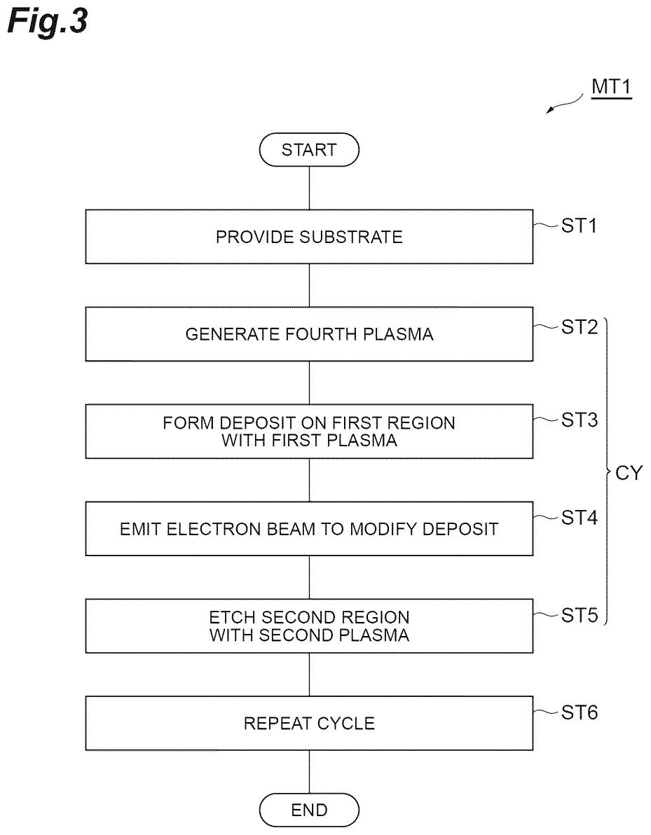

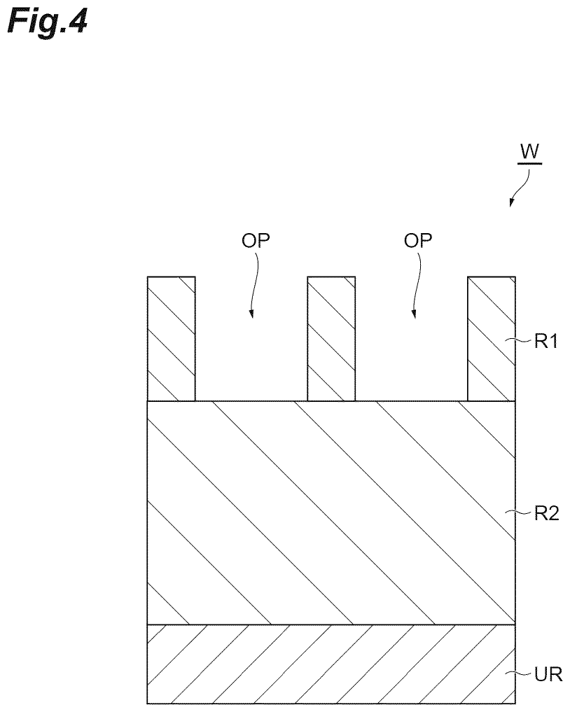

FIG. 3 is a flowchart of an etching method according to one example embodiment. An etching method MT1 illustrated in FIG. 3 (hereinafter, referred to as a “method MT1”) may be executed by the plasma processing apparatus 1 of the above-described embodiment. The method MT1 may be executed by a plasma processing apparatus different from the plasma processing apparatus 1. The method MT1 may be applied to the substrate W in FIG. 4.

FIG. 4 is a cross-sectional view of an example of a substrate to which the method in FIG. 3 may be applied. As illustrated in FIG. 4, in one embodiment, the substrate W includes a first region R1 and a second region R2. The first region R1 may be provided on the second region R2. The first region R1 may be a mask. The first region R1 has at least one opening OP. The at least one opening OP may be a hole, or may be a slit. The first region R1 may have a plurality of openings OP. The second region R2 may be an etching target film. The substrate W may further include an underlying region UR. The underlying region UR may be provided below the second region R2. Each of the first region R1, the second region R2, and the underlying region UR may be a film.

The first region R1 may include metal. The first region R1 may include a metal hard mask. The first region R1 may include carbon-doped tungsten or titanium nitride.

The second region R2 may include a dielectric film. The second region R2 may include a low dielectric constant film (low-k film). The low-k film may have a relative dielectric constant of 3.8 or less. The second region R2 may include silicon and oxygen. The second region R2 may include silicon oxide (SiO₂), or may include SiOCH.

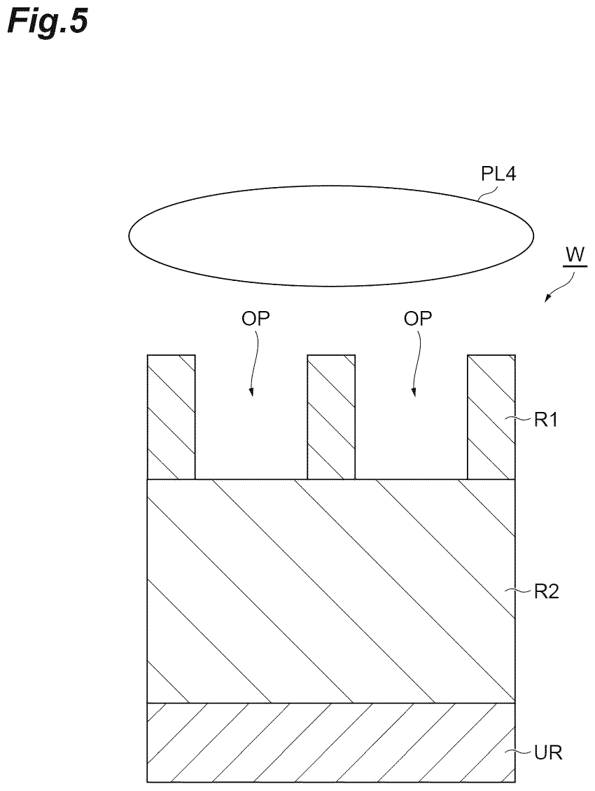

In the following, the method MT1 will be described with reference to FIGS. 3 to 8 by using, as an example, the case where the method MT1 is applied to the substrate W by using the plasma processing apparatus 1 in the above-described embodiment. FIGS. 5 to 8 are partially enlarged cross-sectional views of an example of a substrate related to each step of the etching method according to one example embodiment. In a case where a plasma processing apparatus 1 is used, the method MT1 may be executed in the plasma processing apparatus 1 in a manner that a controller 2 controls each unit of the plasma processing apparatus 1. In the method MT1, as illustrated in FIG. 2, the substrate W on the substrate support 11 disposed in the plasma processing chamber 10 is processed.

As illustrated in FIG. 3, the method MT1 may include Step ST1 to Step ST6. Step ST1 to Step ST6 may be executed in order. Step ST4 may be performed simultaneously with Step ST3, may be performed after Step ST3, may be performed simultaneously with Step ST3, and may be performed after Step ST3. The method MT1 may not include at least one of Step ST2 and Step ST6.

### Step ST1

In Step ST1, the substrate W illustrated in FIG. 4 is provided on the substrate support 11 in the plasma processing chamber 10. Each step of the method MT1 performed after Step ST1 is performed in a state where the substrate W is placed on the substrate support 11.

### Step ST2

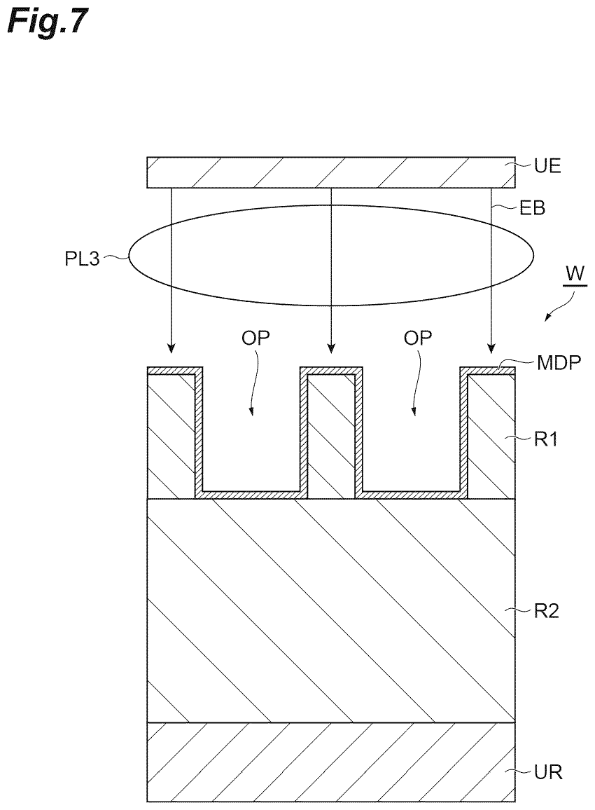

In Step ST2, as illustrated in FIG. 5, a fourth plasma PL4 is generated from a fourth process gas. The fourth process gas may be a gas having a depositing property. The fourth process gas may include fluorine and carbon. The fourth process gas may include at least one of a fluorocarbon gas or a hydrofluorocarbon gas. An example of the fluorocarbon gas includes a C₄F₈ gas. The fourth process gas may further include one or more of a nitrogen-containing gas (for example, a nitrogen gas), an oxygen-containing gas (for example, an oxygen gas), or a noble gas (for example, an Ar gas). In Step ST2, the fourth plasma PL4 is ignited in the plasma processing chamber 10, and radicals are generated from the fourth process gas. Step ST2 may be performed in a state where irradiation with an electron beam EB (see FIG. 7) described later is stopped. Step ST2 may be performed in a state where the electron beam EB is emitted.

Step ST2 may be performed as follows. The fourth process gas is supplied into the plasma processing chamber 10 by the gas supply 20. The controller 2 controls the gas supply 20 and the plasma generator 12 such that the fourth plasma PL4 is generated from the fourth process gas.

In Step ST2, a power level of the source radio frequency power used to generate the fourth plasma PL4 may be higher than a power level of the source radio frequency power used to generate the first plasma PL1 in Step ST3. An electrical bias may not be supplied to the substrate support 11 that supports the substrate W in Step ST2. The controller 2 controls the power supply 30 to adjust the level of the source radio frequency power and the level of the electrical bias.

### Step ST3

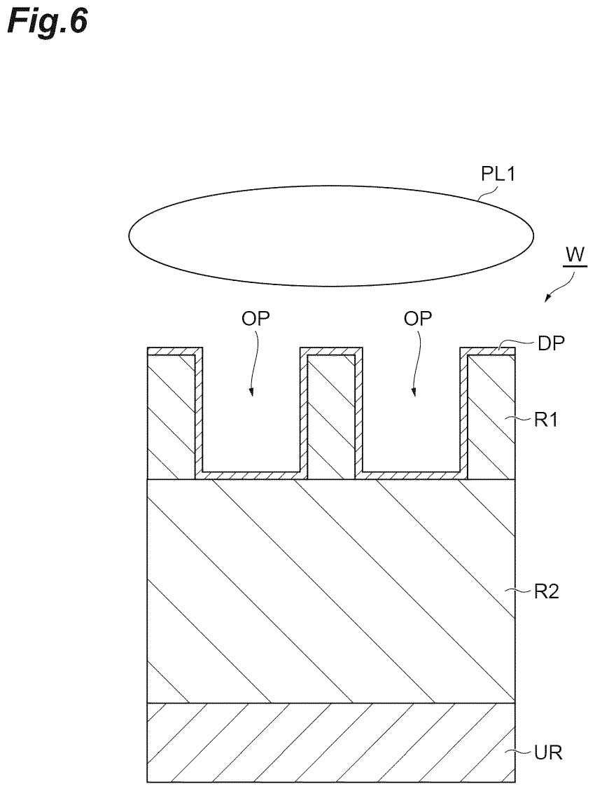

In Step ST3, as illustrated in FIG. 6, the deposit DP is formed on the first region R1 with the first plasma PL1 generated from the first process gas. The deposit DP may be formed on the second region R2. The first process gas may be the same as the fourth process gas. The deposit DP may include at least one of carbon or fluorine. The deposit DP may include at least one of an inter-carbon bond (C—C bond) or a carbon-fluorine bond (C—F bond). The deposit DP may further include oxygen. The deposit DP may include a carbon-oxygen bond (C═O bond or C—O bond). Step ST3 may be performed in a state where irradiation with the electron beam EB (see FIG. 7) described later is stopped. Step ST3 may be performed in a state where the electron beam EB is emitted.

Step ST3 may be performed as follows. The first process gas is supplied into the plasma processing chamber 10 by the gas supply 20. The controller 2 controls the gas supply 20 and the plasma generator 12 such that the first plasma PL1 is generated from the first process gas.

In Step ST3, a power level of the source radio frequency power used to generate the first plasma PL1 may be higher than a power level of the source radio frequency power used to generate the second plasma PL2 in Step ST5. An electrical bias may not be supplied to the substrate support 11 that supports the substrate W in Step ST3. The controller 2 controls the power supply 30 to adjust the level of the source radio frequency power and the level of the electrical bias.

### Step ST4

In Step ST4, as illustrated in FIG. 7, the deposit DP is irradiated with the electron beam EB to modify the deposit DP. As a result, the deposit MDP is generated from the deposit DP. In a case where the deposit DP includes carbon, an element (for example, fluorine or oxygen) other than carbon may be extracted from the deposit DP by the energy of the electron beam EB. The C-F bond, the C═O bond, or the C-O bond in the deposit DP may be dissociated. Therefore, in the deposit MDP obtained in Step ST4, a carbon-carbon bond (C—C bond, C═C bond, or C≡C bond) having a high bonding energy may be formed more than the deposit DP.

In Step ST4, the third plasma PL3 may be generated from the third process gas. The third process gas may be the same as the fourth process gas. The electron beam EB may be generated by applying a negative voltage to the upper electrode UE provided above the substrate W. The upper electrode UE may be included in the shower head 13 of the plasma processing apparatus 1 (see FIG. 2). The negative voltage may be applied from the power supply 30. By applying the negative voltage to the upper electrode UE, cations (for example, Ar ions) in the third plasma PL3 collide with the upper electrode UE. The secondary electrons generated by the sputtering are irradiated onto the substrate W as the electron beam EB. In this case, the upper electrode UE and the power supply 30 constitute an electron beam irradiation source of the electron beam EB.

Step ST4 may be performed as follows. The third process gas is supplied into the plasma processing chamber 10 by the gas supply 20. The controller 2 controls the gas supply 20, the plasma generator 12, and the electron beam irradiation source such that the third plasma PL3 is generated from the third process gas and the substrate W is irradiated with the electron beam EB.

In Step ST4, a power level of the source radio frequency power used to generate the third plasma PL3 may be equal to or higher than a power level of the source radio frequency power used to generate the second plasma PL2 in Step ST5. A level of the electrical bias supplied to the substrate support 11 that supports the substrate W in Step ST4 may be lower than a level of the electrical bias supplied to the substrate support 11 that supports the substrate W in Step ST5. The controller 2 controls the power supply 30 to adjust the level of the source radio frequency power and the level of the electrical bias.

### Step ST5

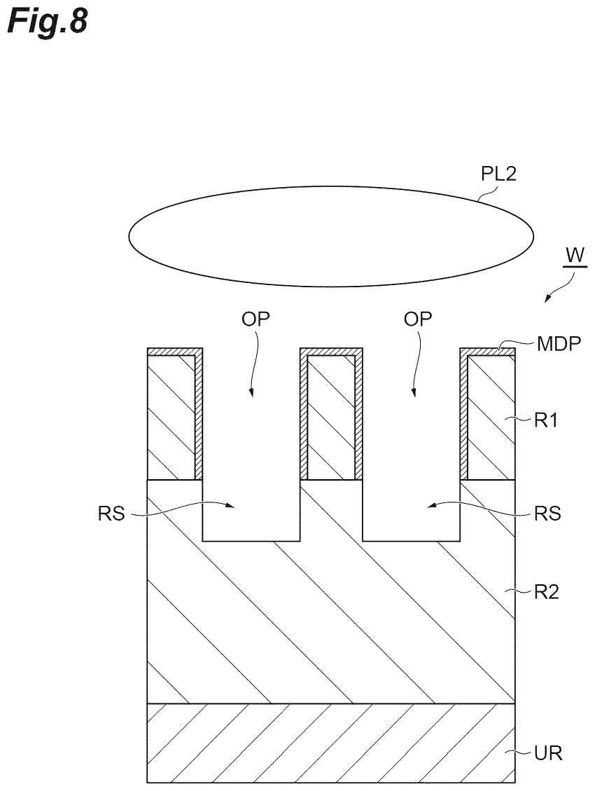

In Step ST5, as illustrated in FIG. 8, the second region R2 is etched with the second plasma PL2 generated from the second process gas in a state where the irradiation with the electron beam EB is stopped. As a result, a recess RS may be formed in the second region R2. The recess RS corresponds to the opening OP of the first region R1. In Step ST5, a voltage may not be applied to the upper electrode UE to stop the irradiation with the electron beam EB. In this case, it is possible to suppress the foreign matter caused by the silicon generated by the sputtering of the upper electrode UE. In addition, it is possible to suppress scavenging and exhaust of the fluorine in the second plasma PL2 by the silicon. Step ST5 may be performed in a state where the electron beam EB is emitted.

Step ST5 may be performed as follows. The second process gas is supplied into the plasma processing chamber 10 by the gas supply 20. The controller 2 controls the gas supply 20 and the plasma generator 12 such that the second plasma PL2 is generated from the second process gas.

The level of the electrical bias supplied to the substrate support 11 that supports the substrate W in Step ST5 may be higher than the level of the electrical bias supplied to the substrate support 11 that supports the substrate W in Step ST3 or Step ST4. The controller 2 controls the power supply 30 to adjust the level of the source radio frequency power and the level of the electrical bias.

### Step ST6

In Step ST6, the cycle CY including Step ST2 to Step ST5 is repeated. The cycle CY may not include Step ST2. The time of each cycle CY may be 1 second or shorter, or may be 1 millisecond or shorter. When the number of times of the cycle CY is increased, the recess RS formed in the second region R2 is deepened.

Step ST6 may be performed as follows. The controller 2 controls the gas supply 20, the plasma generator 12, and the electron beam irradiation source to repeat the cycle CY including Step ST2 to Step ST5.

According to the etching method MT1, the etching resistance of the deposit MDP is improved by the irradiation with the electron beam EB in Step ST4. Therefore, in Step ST5, the reduction of the deposit MDP due to the etching can be suppressed. As a result, the reduction of the first region R1 can also be suppressed.

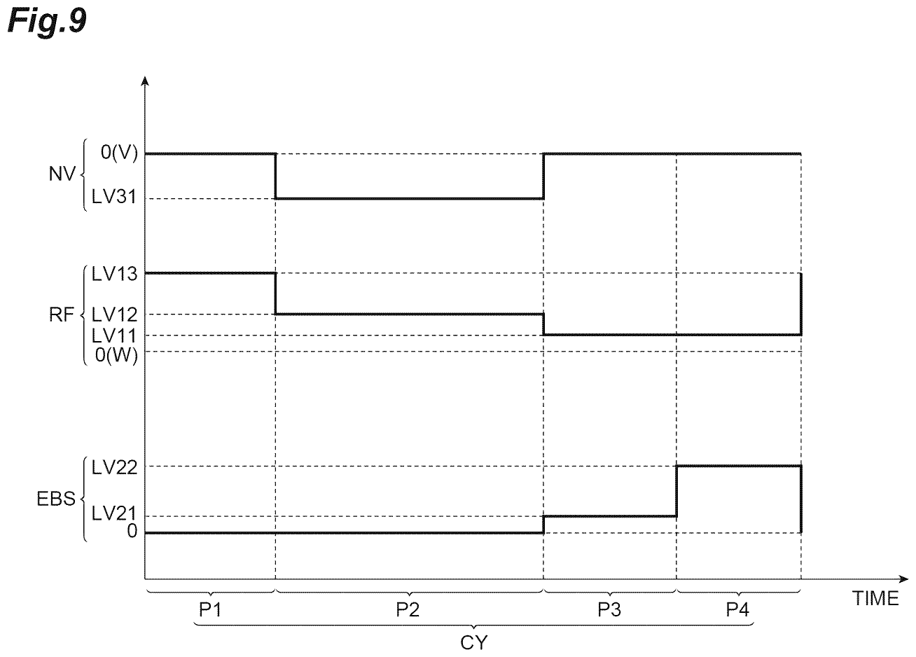

FIG. 9 is a timing chart related to the etching method according to one example embodiment. This timing chart is related to Step ST2 to Step ST5 of the method MT1. A certain cycle CY includes a period P1 to a period P4. A period P2 is a period following the period P1. A period P3 is a period following the period P2. The period P4 is a period following the period P3. The period P1 of the next cycle CY follows the period P4 of the certain cycle CY. In the timing chart of FIG. 9, Step ST2 is performed in the period P1. Step ST3 and Step ST4 are performed simultaneously in the period P2. Step ST5 is performed in the period P4.

In the period P1 (Step ST2), the negative voltage NV applied to the upper electrode UE in FIG. 7 is 0 V. That is, in the period P1, the negative voltage is not applied to the upper electrode UE. In the period P1, the power level of the source radio frequency power RF used to generate the fourth plasma PL4 is a level LV13 higher than 0 W. In the period P1, the level of the electrical bias EBS supplied to the substrate support 11 is 0. That is, in the period P1, the electrical bias EBS is not supplied to the substrate support 11. In the period P1, the fourth plasma PL4 is ignited.

In the present specification, in a case where the electrical bias EBS is the bias radio frequency power, the level of the electrical bias EBS is the power level of the bias radio frequency power. In a case where the electrical bias EBS includes a voltage pulse, the level of the electrical bias EBS is an absolute value of a negative voltage level of the voltage pulse.

In the period P2 (Step ST3 and Step ST4), the absolute value of the negative voltage NV applied to the upper electrode UE in FIG. 7 is a level LV31 higher than 0 V. In the period P2, the power level of the source radio frequency power RF used to generate the first plasma PL1 is a level LV12 higher than 0 W. The level LV12 is lower than the level LV13. In the period P2, the level of the electrical bias EBS supplied to the substrate support 11 is 0. That is, in the period P2, the electrical bias EBS is not supplied to the substrate support 11. In the period P2, the formation and the modification of the deposit DP proceed simultaneously.

In the period P3, the negative voltage NV applied to the upper electrode UE in FIG. 7 is 0 V. That is, in the period P3, the negative voltage is not applied to the upper electrode UE. In the period P3, the power level of the source radio frequency power RF used to generate the third plasma PL3 is a level LV11 higher than 0 W. The level LV11 is lower than the level LV12. In the period P3, the level of the electrical bias EBS supplied to the substrate support 11 is a level LV21 higher than 0.

In the period P4 (Step ST5), the negative voltage NV applied to the upper electrode UE in FIG. 7 is 0 V. That is, in the period P4, the negative voltage is not applied to the upper electrode UE. In the period P4, the power level of the source radio frequency power RF used to generate the second plasma PL2 is a level LV11 higher than 0 W. In the period P4, the level of the electrical bias EBS supplied to the substrate support 11 is a level LV22 higher than 0. The level LV22 is higher than the level LV21. In the period P4, the second region R2 is etched.

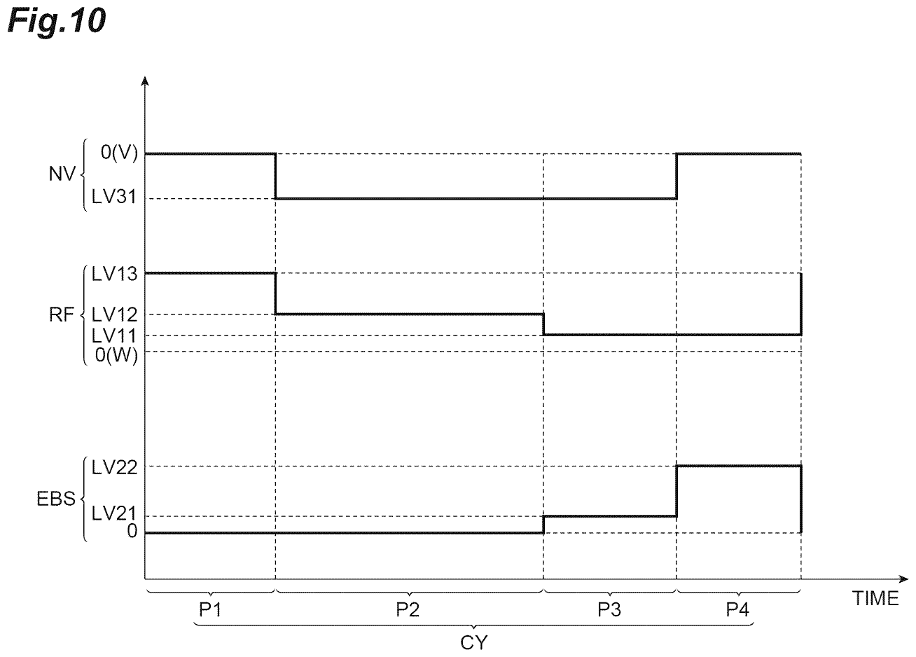

FIG. 10 is a timing chart related to an etching method according to another example embodiment. The timing chart of FIG. 10 is the same as the timing chart of FIG. 9 except for the following points. In the timing chart of FIG. 10, Step ST4 is performed in the period P3 in addition to the period P2. In the period P3, the absolute value of the negative voltage NV applied to the upper electrode UE in FIG. 7 is a level LV31 higher than 0 V.

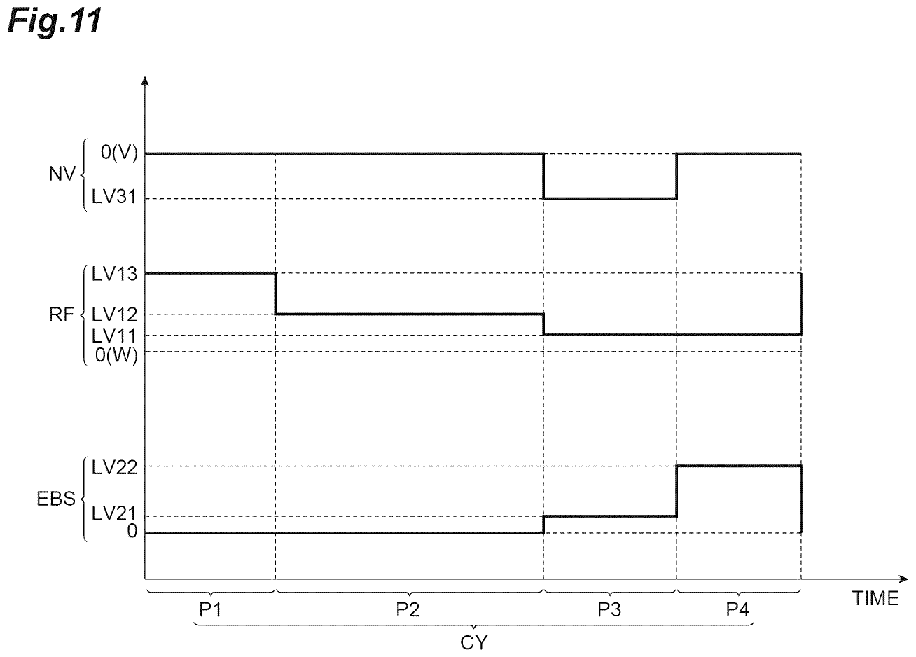

FIG. 11 is a timing chart related to an etching method according to another example embodiment. The timing chart of FIG. 11 is the same as the timing chart of FIG. 9 except for the following points. In the timing chart of FIG. 11, Step ST4 is not performed in the period P2 and is performed in the period P3. In the period P2, the negative voltage NV applied to the upper electrode UE in FIG. 7 is 0 V. That is, in the period P2, the negative voltage is not applied to the upper electrode UE. In the period P3, the absolute value of the negative voltage NV applied to the upper electrode UE in FIG. 7 is a level LV31 higher than 0 V.

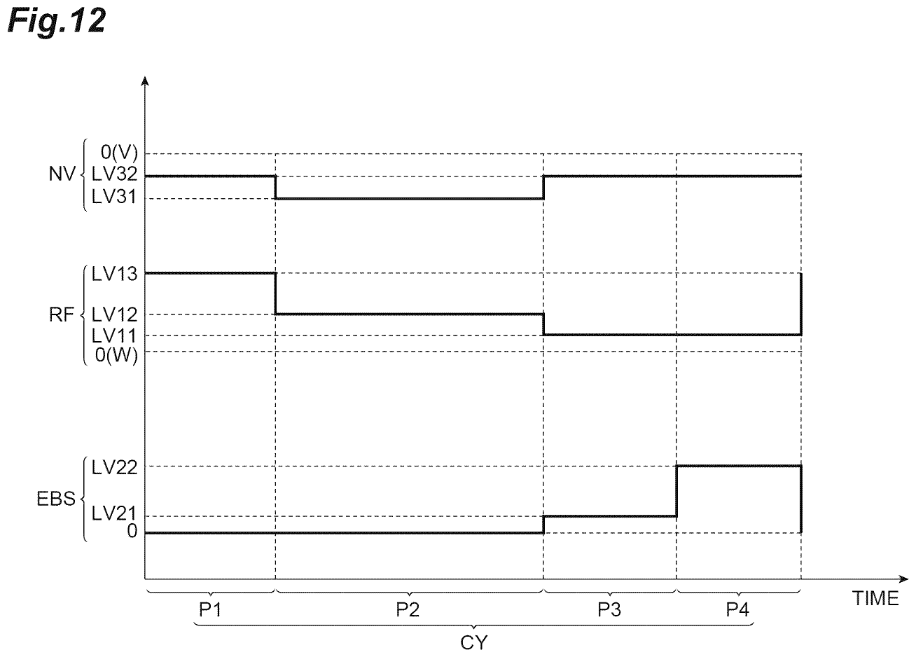

FIG. 12 is a timing chart related to an etching method according to another example embodiment. The timing chart of FIG. 12 is the same as the timing chart of FIG. 9 except for the following points. In the timing chart of FIG. 12, the negative voltage NV is applied to the upper electrode UE in FIG. 7 in the period P1, the period P3, and the period P4. The absolute value of the negative voltage NV is a level LV32. The level LV32 is higher than 0 V and lower than the level LV31. The level LV32 may be less than half of the level LV31. Step ST2 and Step ST5 are performed in a state where the electron beam EB is emitted.

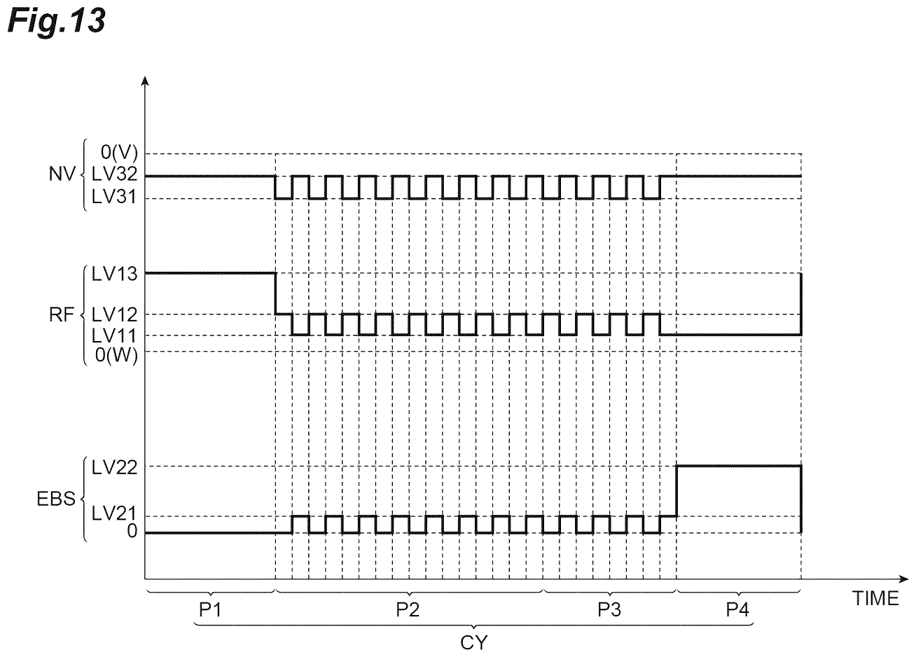

FIG. 13 is a timing chart related to an etching method according to another example embodiment. The timing chart of FIG. 13 is the same as the timing chart of FIG. 12 except for the following points. In the timing chart of FIG. 13, the pulsed negative voltage NV is applied to the upper electrode UE in FIG. 7 in the period P2 and the period P3. In the period P2 and the period P3, the maximum value of the absolute value of the negative voltage NV is the level LV31, and the minimum value of the absolute value of the negative voltage NV is the level LV32. At the beginning of the period P2, the absolute value of the negative voltage NV is the level LV31. At the end of the period P3, the absolute value of the negative voltage NV is the level LV32. The cycle of the pulsed negative voltage NV may be 1 second or shorter, or may be 100 milliseconds or shorter. Step ST3 and Step ST4 are performed in a state where the electron beam EB is emitted in a pulsed manner.

In the timing chart of FIG. 13, the pulsed source radio frequency power RF is supplied in the period P2 and the period P3. The pulsed source radio frequency power RF is synchronized with the pulsed negative voltage NV. In the period P2 and the period P3, the maximum value of the power level of the source radio frequency power RF is the level LV12, and the minimum value of the power level of the source radio frequency power RF is the level LV11. At the beginning of the period P2, the power level of the source radio frequency power RF is the level LV12. At the end of the period P3, the power level of the source radio frequency power RF is the level LV11.

In the timing chart of FIG. 13, the pulsed electrical bias EBS is supplied in the period P2 and the period P3. The pulsed electrical bias EBS is synchronized with the pulsed negative voltage NV and the pulsed source radio frequency power RF. In the period P2 and the period P3, the maximum value of the level of the electrical bias EBS is the level LV21, and the minimum value of the electrical bias EBS is 0. At the beginning of the period P2, the level of the electrical bias EBS is 0. At the end of the period P3, the level of the electrical bias EBS is the level LV21.

In the timing chart of FIG. 13, the period of the level LV31 of the negative voltage NV corresponds to the period of the level LV12 of the source radio frequency power RF, and the period of the level LV32 of the negative voltage NV corresponds to the period of the level LV11 of the source radio frequency power RF, but the present disclosure is not limited thereto. For example, the period of the level LV31 of the negative voltage NV may correspond to the period of the level LV11 of the source radio frequency power RF, and the period of the level LV32 of the negative voltage NV may correspond to the period of the level LV12 of the source radio frequency power RF. Alternatively, the period of the level LV31 of the negative voltage NV may be offset from the period of the level LV12 of the source radio frequency power RF or the period of the level LV11. The period of the level LV32 of the negative voltage NV may be offset from the period of the level LV12 of the source radio frequency power RF or the period of the level LV11.

The power levels of the source radio frequency power RF in the period P1, the period P2, the period P3, and the period P4 are denoted by L_{RF1}, L_{RF2}, L_{RF3}, and L_{RF4}, respectively. In addition, the levels of the electrical bias EBS in the period P1, the period P2, the period P3, and the period P4 are denoted by L_{EB1}, L_{EB2}, L_{EB3}, and L_{EB4}, respectively. The power level of the source radio frequency power RF and the level of the electrical bias EBS in each step of the method MT1 are not limited to the above-described example.

For example, the power level of the source radio frequency power RF may satisfy any of the following (A1) to (A4), and the level of the electrical bias EBS may satisfy any of the following (A5) to (A10).

$$0 \leq {L}_{R F 4} < {L}_{R F 2} < {L}_{R F 3} < {L}_{R F 1} \qquad ( A1 )$$

$$0 < {L}_{R F 2} \leq {L}_{R F 4} < {L}_{R F 3} < {L}_{R F 1} \qquad ( A2 )$$

$$0 < {L}_{R F 2} < {L}_{R F 3} \leq {L}_{R F 4} < {L}_{R F 1} \qquad ( A3 )$$

$$0 < {L}_{R F 2} < {L}_{R F 3} < {L}_{R F 1} \leq {L}_{R F 4} \qquad ( A4 )$$

$$0 \leq {L}_{E B 1} \leq {L}_{E B 2} \leq {L}_{E B 3} < {L}_{E B 4} \qquad ( A5 )$$

$$0 \leq {L}_{E B 2} \leq {L}_{E B 1} \leq {L}_{E B 3} < {L}_{E B 4} \qquad ( A6 )$$

$$0 \leq {L}_{E B 3} \leq {L}_{E B 1} \leq {L}_{E B 2} < {L}_{E B 4} \qquad ( A7 )$$

$$0 \leq {L}_{E B 3} \leq {L}_{E B 2} \leq {L}_{E B 1} < {L}_{E B 4} \qquad ( A8 )$$

$$0 \leq {L}_{E B 1} \leq {L}_{E B 3} \leq {L}_{E B 2} < {L}_{E B 4} \qquad ( A9 )$$

$$0 \leq {L}_{E B 2} \leq {L}_{E B 3} \leq {L}_{E B 1} < {L}_{E B 4} \qquad ( A10 )$$

Alternatively, the power level of the source radio frequency power RF may satisfy any of the following (B1) to (B4), and the level of the electrical bias EBS may satisfy any of the following (B5) to (B10).

$$0 \leq {L}_{R F 4} < {L}_{R F 2} < {L}_{R F 1} < {L}_{R F 3} \qquad ( B1 )$$

$$0 < {L}_{R F 2} \leq {L}_{R F 4} < {L}_{R F 1} < {L}_{R F 3} \qquad ( B2 )$$

$$0 < {L}_{R F 2} < {L}_{R F 1} \leq {L}_{R F 4} < {L}_{R F 3} \qquad ( B3 )$$

$$0 < {L}_{R F 2} < {L}_{R F 1} < {L}_{R F 3} \leq {L}_{R F 4} \qquad ( B4 )$$

$$0 \leq {L}_{EB 1} \leq {L}_{E B 2} \leq {L}_{EB 3} < {L}_{EB 4} \qquad ( B5 )$$

$$0 \leq {L}_{EB 2} \leq {L}_{EB 1} \leq {L}_{EB 3} < {L}_{EB 4} \qquad ( B6 )$$

$$0 \leq {L}_{EB 3} \leq {L}_{EB 1} \leq {L}_{EB 2} < {L}_{EB 4} \qquad ( B7 )$$

$$0 \leq {L}_{EB 3} \leq {L}_{EB 2} \leq {L}_{EB 1} < {L}_{EB 4} \qquad ( B8 )$$

$$0 \leq {L}_{EB 1} \leq {L}_{EB 3} \leq {L}_{EB 2} < {L}_{EB 4} \qquad ( B9 )$$

$$0 \leq {L}_{EB 2} \leq {L}_{EB 3} \leq {L}_{EB 1} < {L}_{EB 4} \qquad ( B10 )$$

Alternatively, the power level of the source radio frequency power RF may satisfy any of the following (C1) to (C4), and the level of the electrical bias EBS may satisfy any of the following (C5) to (C7).

$$0 \leq {L}_{R F 4} < {L}_{R F 3} \leq {L}_{R F 2} < {L}_{R F 1} \qquad ( C1 )$$

$$0 < {L}_{R F 3} \leq {L}_{R F 4} \leq {L}_{R F 2} < {L}_{R F 1} \qquad ( C2 )$$

$$0 < {L}_{R F 3} \leq {L}_{R F 2} \leq {L}_{R F 4} < {L}_{R F 1} \qquad ( C3 )$$

$$0 < {L}_{R F 3} \leq {L}_{R F 2} < {L}_{R F 1} \leq {L}_{R F 4} \qquad ( C4 )$$

$$0 \leq {L}_{EB 1} < {L}_{EB 3} < {L}_{EB 3} < {L}_{EB 4} \qquad ( C5 )$$

$$0 < {L}_{EB 3} \leq {L}_{EB 1} < {L}_{EB 3} < {L}_{EB 4} \qquad ( C6 )$$

$$0 < {L}_{EB 3} < {L}_{EB 3} \leq {L}_{EB 1} < {L}_{EB 4} \qquad ( C7 )$$

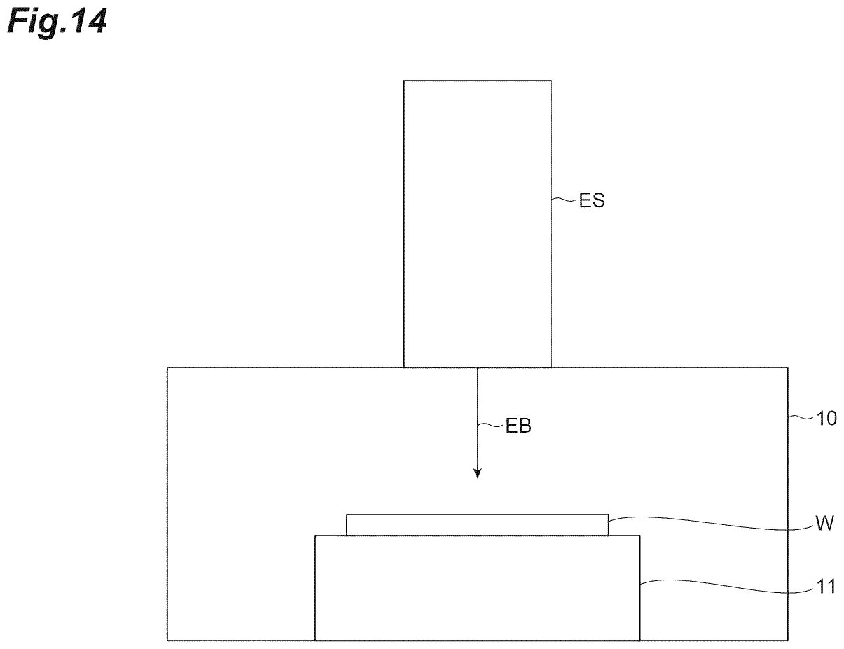

FIG. 14 is a diagram for describing a configuration example of a plasma processing apparatus including an electron beam irradiation source. The plasma processing apparatus illustrated in FIG. 14 further includes an electron beam irradiation source ES in addition to the configuration of the plasma processing apparatus 1 in FIG. 2. The electron beam irradiation source ES is, for example, an electron gun. The electron beam irradiation source ES is attached to the plasma processing chamber 10 above the substrate W. The electron beam irradiation source ES is configured to irradiate the substrate W in the plasma processing chamber 10 with an electron beam EB. The controller 2 (FIG. 2) may be configured to control the electron beam irradiation source ES to emit the electron beam EB in a pulsed (intermittent) manner while repeating on and off of the electron beam EB. As a result, the substrate W can be irradiated with the electron beam EB in Step ST4, and the irradiation with the electron beam EB can be stopped in the other steps (Step ST2, Step ST3, or Step ST5).

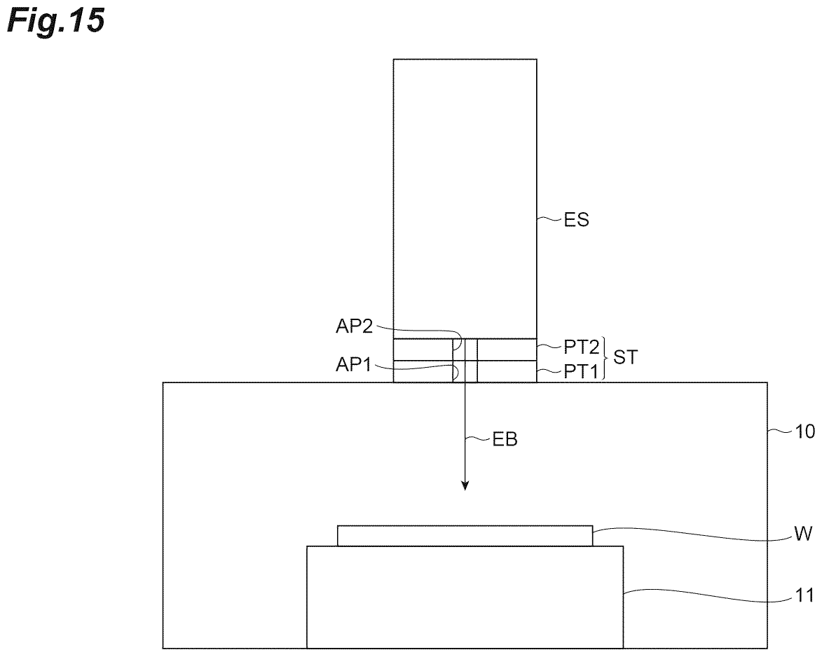

FIG. 15 is a diagram for describing another configuration example of the plasma processing apparatus including the electron beam irradiation source. The plasma processing apparatus illustrated in FIG. 15 further includes an electron beam irradiation source ES and a shutter ST in addition to the configuration of the plasma processing apparatus 1 in FIG. 2. The shutter ST is disposed between the electron beam irradiation source ES and the plasma processing chamber 10. The shutter ST is, for example, a micro electro mechanical systems (MEMS) shutter. The shutter ST includes a plate-like member PT1 having an aperture AP1 for transmitting the electron beam EB and a plate-like member PT2 having an aperture AP2 for transmitting the electron beam EB. The plate-like member PT1 and the plate-like member PT2 are movable relative to each other between a first position at which the aperture AP1 and the aperture AP2 overlap each other and a second position at which the aperture AP1 and the aperture AP2 do not overlap each other. At the first position, the electron beam EB emitted from the electron beam irradiation source ES reaches the inside of the plasma processing chamber 10. At the second position, since the electron beam EB emitted from the electron beam irradiation source ES is blocked by the shutter ST, the electron beam EB does not reach the inside of the plasma processing chamber 10. The shutter ST can be repeatedly and periodically opened and closed. The controller 2 (FIG. 2) may be configured to control the opening and closing of the shutter ST such that the substrate W is irradiated with the electron beam EB in a pulsed (intermittent) manner. In this case, the electron beam EB does not need to be emitted in a pulsed manner from the electron beam irradiation source ES, and may be continuously emitted from the electron beam irradiation source ES. When the electron beam irradiation source ES and the shutter ST are used, the substrate W can be irradiated with the electron beam EB in Step ST4, and the irradiation with the electron beam EB can be stopped in other steps (Step ST2, Step ST3, or Step ST5).

According to the plasma processing apparatuses in FIGS. 14 and 15, the electron beam EB can be generated without applying a negative voltage to the upper electrode UE. According to the plasma processing apparatuses in FIGS. 14 and 15, for example, the method MT1 can be performed according to the timing charts of FIGS. 9 to 13.

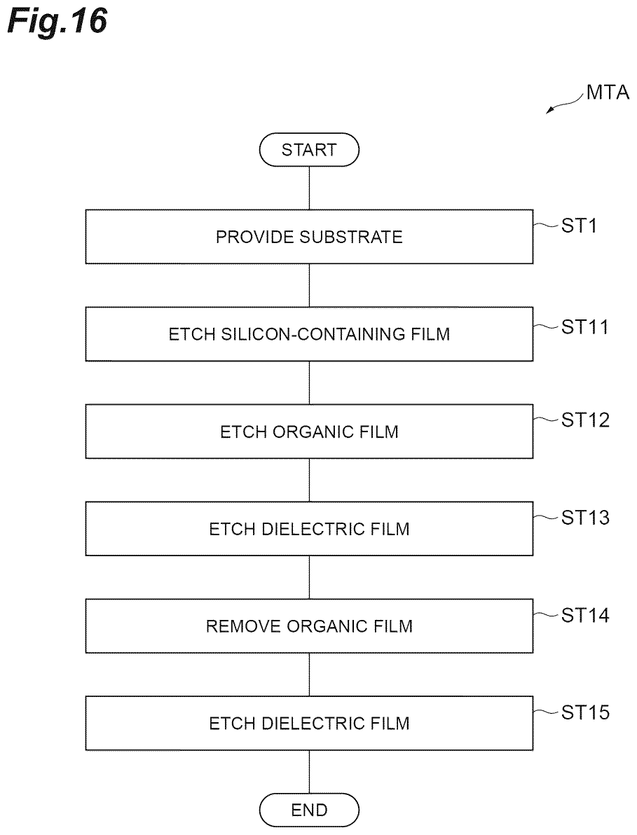

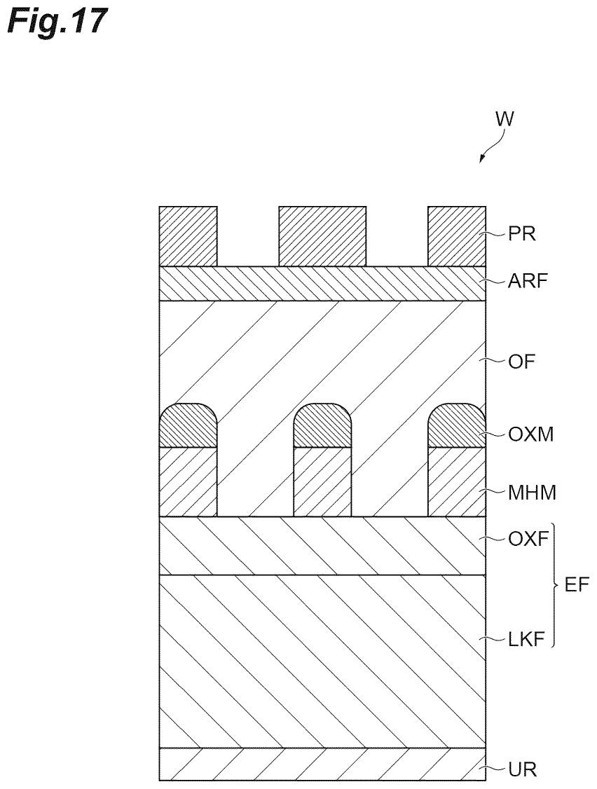

Hereinafter, an etching method according to another example embodiment will be described with reference to FIGS. 16 to 20. FIG. 16 is a flowchart of an etching method according to another example embodiment. FIGS. 17 to 20 are partially enlarged cross-sectional views of an example of a substrate related to each step of the etching method according to another example embodiment. Hereinafter, the etching method (hereinafter, referred to as a “method MTA”) illustrated in FIG. 16 will be described with a case where the plasma processing apparatus 1 is used as an example. The method MTA may be performed using a plasma processing apparatus different from the plasma processing apparatus 1. The method MTA may be performed using the plasma processing apparatuses in FIGS. 14 and 15.

The method MTA is applied to a substrate W illustrated in FIG. 17. As illustrated in FIG. 17, the substrate W includes an underlying region UR, a film EF, a metal hard mask MHM, a silicon oxide film OXM, an organic film OF, a silicon-containing film ARF, and a resist mask PR. The metal hard mask MHM is an example of a first region R1 in FIG. 4. The film EF is an example of a second region R2 in FIG. 4.

The underlying region UR is, for example, an etching stop layer. The underlying region UR may have a laminated structure including an aluminum oxide film and a SiCN film. The film EF is provided on the underlying region UR. The film EF is a dielectric film, and may include silicon and oxygen. In one embodiment, the film EF may include a low dielectric constant film LKF. The film EF may have a laminated structure including the low dielectric constant film LKF and the silicon oxide film OXF. The low dielectric constant film LKF may be a SiOCH film.

The metal hard mask MHM is provided on the film EF. The metal hard mask MHM has a pattern transferred to the film EF by etching. That is, the metal hard mask MHM provides one or more openings. The metal hard mask MHM is formed of, for example, titanium nitride. The metal hard mask MHM may be formed of another metal-containing material.

The silicon oxide film OXM is provided on the top of the metal hard mask MHM. The organic film OF is provided to cover the silicon oxide film OXM, the metal hard mask MHM, and the film EF. The silicon-containing film ARF is provided on the organic film OF. The silicon-containing film ARF may be an anti-reflective film. The resist mask PR is provided on the silicon-containing film ARF. The resist mask PR is patterned using a photolithography technology. The resist mask PR is provided with one or more openings to form a recess (for example, a trench or a hole) in the film EF at a portion exposed from the metal hard mask MHM.

Referring back to FIG. 16, the method MTA includes Step ST1. In Step ST1 of the method MTA, the substrate W (see FIG. 17) is provided on the substrate support 11 in the plasma processing chamber 10 of the plasma processing apparatus 1, as in Step ST1 of the method MT1. The steps of the method MTA performed after Step ST1 are performed in a state where the substrate W is placed on the substrate support 11.

In the method MTA, Step ST11 is performed after Step ST1. In Step ST11, the silicon-containing film ARF is etched. In Step ST11, the pattern of the resist mask PR is transferred to the silicon-containing film ARF. In Step ST11, plasma is generated from an etching gas in the plasma processing chamber 10 for etching the silicon-containing film ARF. The etching gas used in Step ST11 includes a fluorocarbon gas and a noble gas (for example, an Ar gas).

In Step ST11, the controller 2 controls the gas supply 20 to supply the etching gas into the plasma processing chamber 10. In Step ST11, the controller 2 controls the gas exhaust system 40 to set the pressure in the plasma processing chamber 10 to a designated pressure. In Step ST11, the controller 2 controls the power supply 30 so that the source radio frequency power RF is supplied to the radio frequency electrode to generate the plasma from the etching gas. In Step ST11, the controller 2 may control the power supply 30 to supply the electrical bias EBS to the bias electrode.

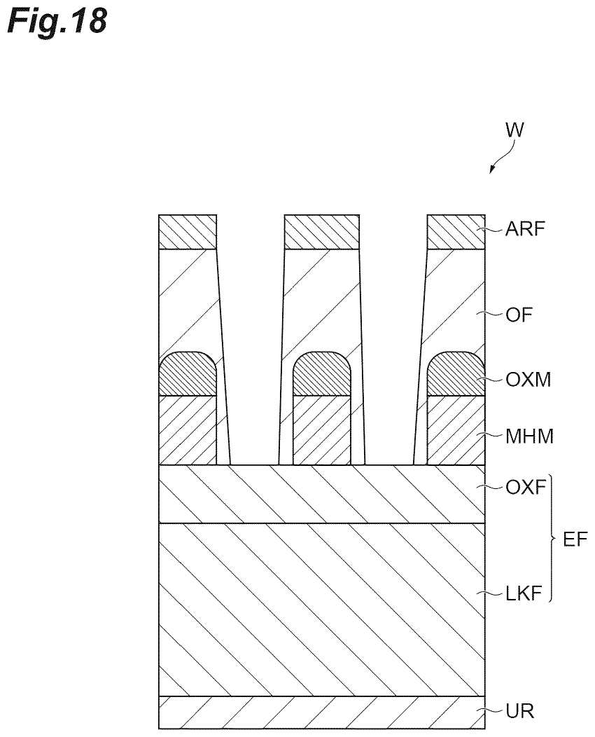

Next, Step ST12 is performed. In Step ST12, the organic film OF is etched. In Step ST12, as illustrated in FIG. 18, the pattern of the silicon-containing film ARF is transferred to the organic film OF. In Step ST12, plasma is generated from the etching gas in the plasma processing chamber 10 for etching the organic film OF. The etching gas used in Step ST12 includes an oxygen-containing gas (for example, an oxygen gas). Alternatively, the etching gas used in Step ST12 may include a nitrogen gas and a hydrogen gas.

In Step ST12, the controller 2 controls the gas supply 20 to supply the etching gas into the plasma processing chamber 10. In Step ST12, the controller 2 controls the gas exhaust system 40 to set the pressure in the plasma processing chamber 10 to a designated pressure. In Step ST12, the controller 2 controls the power supply 30 so that the source radio frequency power RF is supplied to the radio frequency electrode to generate the plasma from the etching gas. In Step ST12, the controller 2 may control the power supply 30 to supply the electrical bias EBS to the bias electrode.

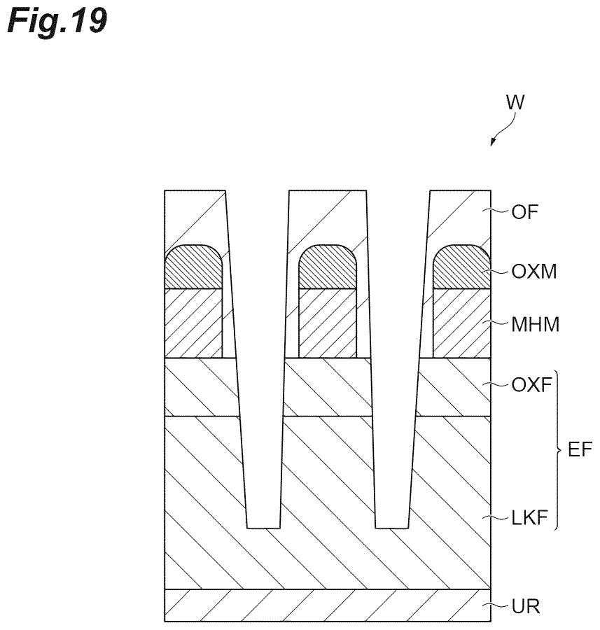

Next, Step ST13 is performed. In Step ST13, the film EF is etched. In Step ST13, Step ST2 to Step ST6 (see FIG. 3) in the above-described method MT1 are performed. In Step ST13, as illustrated in FIG. 19, the pattern of the organic film OF is transferred to the film EF, and the recess is formed in the film EF.

Next, Step ST14 is performed. In Step ST14, the organic film OF is removed. In Step ST14, plasma is generated from an ashing gas in the plasma processing chamber 10 to remove the organic film OF. The ashing gas used in Step ST14 includes an oxygen-containing gas (for example, an oxygen gas and/or a CO gas).

In Step ST14, the controller 2 controls the gas supply 20 to supply the ashing gas into the plasma processing chamber 10. In Step ST14, the controller 2 controls the gas exhaust system 40 to set the pressure in the plasma processing chamber 10 to a designated pressure. In Step ST14, the controller 2 controls the power supply 30 so that the source radio frequency power RF is supplied to the radio frequency electrode to generate the plasma from the etching gas.

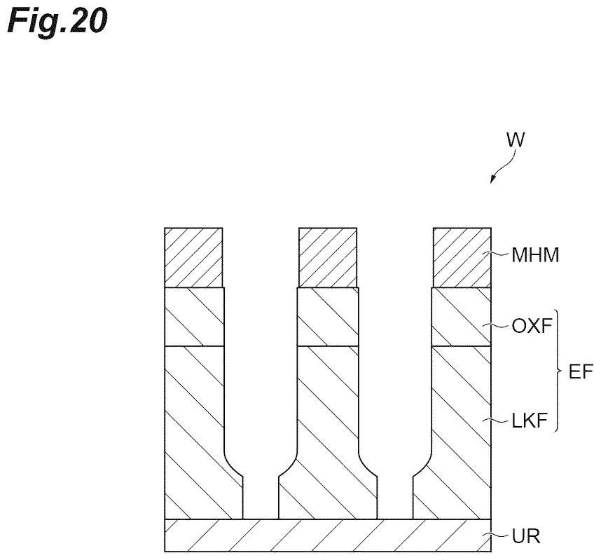

Next, Step ST15 is performed. In Step ST15, as illustrated in FIG. 20, the film EF is further etched to increase the depth of the recess. In Step ST15, Step ST2 to Step ST6 (see FIG. 3) in the above-described method MT1 are performed.

According to the method MTA, similarly to the method MT1, the metal hard mask MHM is protected by the deposit MDP (see FIG. 7) during the etching of the film EF in Step ST13 and Step ST15. Therefore, the reduction of the metal hard mask MHM due to the etching of the film EF is suppressed. In addition, according to the method MTA, even when the pattern of the resist mask PR is shifted with respect to the pattern of the metal hard mask MHM, it is possible to proceed with the etching of the film EF while suppressing the reduction of the metal hard mask MHM. When the pattern of the resist mask PR is shifted with respect to the pattern of the metal hard mask MHM, the silicon oxide film OXM may be exposed in Step ST12. In this case, when the exposed silicon oxide film OXM is etched in Step ST13, the metal hard mask MHM may be exposed and etched. Even in such a case, the metal hard mask MHM is protected by the deposit MDP.

Hereinafter, various experiments performed for the evaluation of the method MT1 and the method MTA will be described. The experiments described below do not limit the present disclosure.

### First Experiment

In a first experiment, first, a substrate is provided on a substrate support in a chamber of the plasma processing apparatus (Step ST1). The substrate includes a titanium nitride film on the surface.

Next, a deposit was formed on the titanium nitride film with plasma generated from a fluorocarbon gas (Step ST3). The deposit includes carbon and fluorine.

Next, plasma generated from an Ar gas was generated, and a negative voltage (−900 V) was applied to the upper electrode provided above the substrate. In this way, the substrate was irradiated with an electron beam generated by sputtering of the upper electrode (Step ST4). The duration of Step ST4 is 30 seconds.

Next, the substrate was processed with plasma for etching the silicon oxide film (Step ST5).

### Second Experiment

In a second experiment, the experiment was performed in the same manner as in the first experiment, except that a negative voltage was not applied to the upper electrode in Step ST4. In the second experiment, the deposit on the titanium nitride film was not irradiated with an electron beam.

### Third Experiment

In a third experiment, the experiment was performed in the same manner as in the first experiment, except that Step ST4 was not performed. In the third experiment, the deposit on the titanium nitride film was not irradiated with an electron beam.

### Experimental Results

The cross section of the substrate was observed before and after Step ST5, and the amount of decrease in the thickness of the deposit due to Step ST5 was measured. The amount of decrease in the thickness of the deposit in the first experiment was 11.3 nm. The amount of decrease in the thickness of the deposit in the second experiment was 16.3 nm. The amount of decrease in the thickness of the deposit in the third experiment was 16.1 nm.

In addition, the C—C bond and the C—F bond in the deposit were measured by X-ray photoelectron spectroscopy (XPS). As a result, in the first experiment, the ratio of the C—C bond to the C—F bond (CC/CF ratio) in the vicinity of the surface of the deposit was large, 1 or more. On the other hand, in the second experiment and the third experiment, the CC/CF ratio in the vicinity of the surface of the deposit was small, less than 1.

From the above, it was found that, in a case where the deposit was irradiated with the electron beam, since the CC/CF ratio in the vicinity of the surface of the deposit was increased, the etching resistance of the deposit was improved.

Although the various example embodiments have been described above, various additions, omissions, substitutions, and changes may be made without being limited to the example embodiments described above. In addition, other embodiments can be formed by combining elements in different embodiments.

Here, the various example embodiments included in the present disclosure are described in [E1] to [E17] below.

### [E1]

An etching method including
(a) providing a substrate, the substrate including a first region and a second region,
(b) forming a deposit on the first region with a first plasma generated from a first process gas,
(c) irradiating the deposit with an electron beam to modify the deposit, simultaneously with the (b) or after the (b), and
(d) etching the second region with a second plasma generated from a second process gas, after the (c), in a state where the irradiation with the electron beam is stopped.

According to the etching method, the etching resistance of the deposit is improved by the irradiation with the electron beam.

### [E2]

The etching method according to [E1], further including (e) repeating a cycle including the (b), the (c), and the (d).

### [E3]

The etching method according to [E1] or [E2], in which the deposit includes at least one of carbon or fluorine.

### [E4]

The etching method according to any one of [E1] to [E3], in which
in the (c), a third plasma is generated from a third process gas, and
the electron beam is generated by applying a negative voltage to an upper electrode provided above the substrate.

### [E5]

The etching method according to any one of [E1] to [E4], in which the first region includes a metal hard mask.

### [E6]

The etching method according to any one of [E1] to [E5], in which the second region includes a dielectric film.

### [E7]

The etching method according to any one of [E1] to [E6], in which a level of an electrical bias supplied to a substrate support that supports the substrate in the (d) is higher than a level of an electrical bias supplied to the substrate support that supports the substrate in the (b) or the (c).

In this case, the etching is promoted in the (d).

### [E8]

The etching method according to any one of [E1] to [E7], in which the first process gas includes fluorine and carbon.

### [E9]

The etching method according to any one of [E1] to [E8], in which the second process gas is the same as the first process gas.

### [E10]

The etching method according to [E2] or any one of [E3] to [E9] citing [E2], in which
the cycle further includes (f) generating a fourth plasma from a fourth process gas, before the (b), and
a power level of a source radio frequency power used for generating the fourth plasma is higher than a power level of the source radio frequency power used for generating the first plasma.

### [E11]

The etching method according to any one of [E1] to [E10], in which the (c) is performed after the (b).

### [E12]

The etching method according to [E11], in which the (b) is performed in a state where the irradiation with the electron beam is stopped.

### [E13]

The etching method according to any one of [E1] to [E12], in which the (c) is performed simultaneously with (b).

### [E14]

The etching method according to any one of [E1] to [E13], in which the (c) is performed simultaneously with the (b) and is also performed after the (b).

### [E15]

A plasma processing apparatus including
a chamber,
a substrate support for supporting a substrate in the chamber, the substrate including a first region and a second region,
a gas supply configured to supply a first process gas and a second process gas into the chamber,
a plasma generator configured to generate a first plasma and a second plasma from the first process gas and the second process gas in the chamber, respectively,
an electron beam irradiation source for irradiating an interior of the chamber with an electron beam, and
a controller, in which
the controller is configured to control the gas supply, the plasma generator, and the electron beam irradiation source to execute an etching method including
   (b) forming a deposit on the first region with the first plasma,
   (c) irradiating the deposit with the electron beam to modify the deposit, simultaneously with the (b) or after the (b), and
   (d) etching the second region with the second plasma, after the (c), in a state where the irradiation with the electron beam is stopped.

### [E16]

An etching method including
(a) providing a substrate, the substrate including a first region and a second region,
(b) forming a deposit on the first region with a first plasma generated from a first process gas,
(c) irradiating the deposit with an electron beam to modify the deposit, simultaneously with the (b) or after the (b), and
(d) etching the second region with a second plasma generated from a second process gas, after the (c).

### [E17]

A plasma processing apparatus including
a chamber,
a substrate support for supporting a substrate in the chamber, the substrate including a first region and a second region,
a gas supply configured to supply a first process gas and a second process gas into the chamber,
a plasma generator configured to generate a first plasma and a second plasma from the first process gas and the second process gas in the chamber, respectively,
an electron beam irradiation source for irradiating an interior of the chamber with an electron beam, and
a controller, in which
the controller is configured to control the gas supply, the plasma generator, and the electron beam irradiation source to execute an etching method including
   (b) forming a deposit on the first region with the first plasma,
   (c) irradiating the deposit with the electron beam to modify the deposit, simultaneously with the (b) or after the (b), and
   (d) etching the second region with the second plasma, after the (c).

According to one example embodiment, there are provided an etching method and a plasma processing apparatus capable of improving etching resistance of a deposit formed on a substrate.

From the above description, it will be understood that various embodiments of the present disclosure have been described in the present specification for purposes of illustration, and that various modifications may be made without departing from the scope and spirit of the present disclosure. Accordingly, the various embodiments disclosed in the present specification are not intended to be limiting, with the true scope and spirit being indicated by the following claims.

What is claimed is:

1. An etching method comprising:
providing a substrate, the substrate including a first region and a second region;
forming a deposit on the first region with a first plasma generated from a first process gas;
irradiating the deposit with an electron beam to modify the deposit, simultaneously with the forming a deposit or after the forming a deposit; and
etching the second region with a second plasma generated from a second process gas, after the irradiating the deposit, in a state where the irradiation with the electron beam is stopped.

2. The etching method according to claim 1, further comprising:
repeating a cycle including the forming a deposit, the irradiating the deposit, and the etching the second region.

3. The etching method according to claim 1, wherein the deposit includes at least one of carbon or fluorine.

4. The etching method according to claim 1, wherein
in the irradiating the deposit, a third plasma is generated from a third process gas, and
the electron beam is generated by applying a negative voltage to an upper electrode provided above the substrate.

5. The etching method according to claim 1, wherein the first region includes a metal hard mask.

6. The etching method according to claim 1, wherein the second region includes a dielectric film.

7. The etching method according to claim 1, wherein
a level of an electrical bias supplied to a substrate support that supports the substrate in the etching the second region is higher than a level of an electrical bias supplied to the substrate support that supports the substrate in the forming a deposit or the irradiating the deposit.

8. The etching method according to claim 1, wherein the first process gas includes fluorine and carbon.

9. The etching method according to claim 1, wherein the second process gas is the same as the first process gas.

10. The etching method according to claim 2, wherein
the cycle further includes generating a fourth plasma from a fourth process gas, before the forming a deposit, and
a power level of a source radio frequency power used for generating the fourth plasma is higher than a power level of the source radio frequency power used for generating the first plasma.

11. The etching method according to claim 1, wherein
the irradiating the deposit is performed after the forming a deposit.

12. The etching method according to claim 11, wherein
the forming a deposit is performed in a state where the irradiation with the electron beam is stopped.

13. The etching method according to claim 1, wherein
the irradiating the deposit is performed simultaneously with the forming a deposit.

14. The etching method according to claim 1, wherein
the irradiating the deposit is performed simultaneously with the forming a deposit and is also performed after the forming a deposit.

15. A plasma processing apparatus comprising:
a chamber;
a substrate support for supporting a substrate in the chamber, the substrate including a first region and a second region;
a gas supply configured to supply a first process gas and a second process gas into the chamber;
a plasma generator configured to generate a first plasma and a second plasma from the first process gas and the second process gas in the chamber, respectively;
an electron beam irradiation source configured to irradiate an interior of the chamber with an electron beam; and
a circuitry configured to control the gas supply, the plasma generator, and the electron beam irradiation source to execute an etching method including
forming a deposit on the first region with the first plasma,
irradiating the deposit with the electron beam to modify the deposit, simultaneously with the forming a deposit or after the forming a deposit, and
etching the second region with the second plasma, after the irradiating the deposit, in a state where the irradiation with the electron beam is stopped.

16. An etching method comprising:
providing a substrate, the substrate including a first region and a second region;
forming a deposit on the first region with a first plasma generated from a first process gas;
irradiating the deposit with an electron beam to modify the deposit, simultaneously with the forming a deposit or after the forming a deposit; and
etching the second region with a second plasma generated from a second process gas, after the irradiating the deposit.
